(19) United States
(12) Patent Application Publication
(10) Pub. No.: US 2010/0195286 A1
(43) Pub. Date: Aug. 5, 2010

(54) HEAT SINK MECHANISM FOR INTERNALLY INTEGRATED INVERTER HUB (I3H) MOTOR FOR LIGHT ELECTRIC VEHICLES

(76) Inventors: RAKESH KUMAR DHAWAN, DULLES, VA (US); ERNIE SHIK KIM, DULLES, VA (US); JEREMY DOUGLAS BOYLE, FALLS CHURCH, VA (US); MANSOUR PEYGHATEH, STERLING, VA (US); MOHAMMED ZIAUR RAHMAN, HERNDON, VA (US); STEPHEN HOWARD SAYRE, LEESBURGH, VA (US)

Correspondence Address: Electric Motion Systems, LLC, 45150 Business Court , Ste. 300, Dulles, VA, 20166, US

(21) Appl. No.: 12/363,795

(22) Filed: Feb. 2, 2009

(51) Int. Cl. H05K 7/20

(52) U.S. Cl. 361/717; 903/904

(57) ABSTRACT

A heat sink assembly having excellent heat dissipation for internally integrated inverter hub motor for light electric vehicles and comprising of a thermally conducive ring, the electronic board consisting of multiple inverter switches, a potential secondary electronic board and a heat sink base, where the thermally conductive one piece ring is pressed down on the inverter switches to affix the switches to the hub of the motor thereby creating a mechanism for heat dissipation.

### FIELD OF THE INVENTION

The present invention relates generally to a light electric vehicle hub motor system, and more particularly to a heat sink having excellent heat dissipation for internally integrated inverter hub motor for light electric vehicles.

### BACKGROUND OF THE INVENTION

Generally the Light Electric Vehicles use hub motors as propulsion units. Some hub motors have the DC to AC inverter integrated internally with the motor. Heat dissipation from inverter switches becomes a challenge for such motors as heat generated by the inverter and motor windings are trapped inside the hub of the wheel. Effectively cooling the heat generating parts of the hub motors and components, etc. is an important problem to be solved. Also, a cooling system for the heat generating parts is required to be small in size.

The conventional inventions are the heat generating parts of the electric and electronic components, etc. have been cooled by thermally connecting a heat sink of aluminum or aluminum alloy to the heat generating part. However, because aluminum or aluminum alloy has a low thermal conductivity, heat diffusion by the heat sink is insufficient. Thus, a sufficient cooling effect cannot be obtained. This problem has so far been solved by making a large-sized heat sink. However, the heat generating parts have been made small and the calorific value has increased, hence a heat sink having higher performance and smaller size has been in strong demand in order to put off the heat generated during the run time of hub motors.

Accordingly, improvements are needed in the existing inverter switches and heat sink mechanism for the fulfillment of a heat sink mechanism having excellent heat dissipation properties for use in an internally integrated inverter hub motor for light electric vehicles.

The relevant prior art methods, which will deal with improvements in hub motors and concerning the heat sink mechanism, are as follows:

U.S. Pat. No. 5,237,494 describes an apparatus for driving a plurality of motors at different variable speeds. The apparatus includes a rectifier for supplying direct current power to a DC bus circuit. A plurality of inverters are connected to the DC bus circuit and each inverter drives a respective motor. Each inverter is controlled by an individual controller connected thereto for controlling the frequency of the output of the inverter to thereby control the speed of the associated motor. The inverters are preferably mounted on a common heat sink to reduce electrical and mechanical complexity. The apparatus permits the rectifier and the DC bus circuit to be sized to handle a maximum rating of less than the sum total of maximum loads of each of the motors. The DC bus circuit also serves to distribute energy generated by a slowing motor, for example, to other motors driven from the bus circuit. A chopper resistor may be included and switched across the DC bus circuit to provide braking to the motors.

U.S. Pat. No. 5,472,324 reveals a page pack for a printing press wherein the housing for the ink pump and motor assemblies also serves as a heat sink for the heat generated by the motor drive units. The housing comprises a body for receiving a plurality of positive displacement ink pumps each comprising a pump cylinder and at least one pump piston, with all such bores being arranged substantially parallel to each other and lying in a given plane. The housing includes openings for accommodating pump drive motors with their output shafts arranged so as to lie parallel to each other and in a plane slightly offset from an intersecting plane in which the pumps are positioned. The pump housing further includes means for positioning a motor control circuit board in the housing such that a plurality of individual high current driver units each has its own metal heat sink, and such that these individual heat sinks are secured in use to a master metal heat sink either positioned adjacent or forming a part of the housing, whereby there is an intimate heat exchange relation between the motor driver units and the housing.

U.S. Pat. No. 5,966,291 explains a power module for the control of electric motors is described which displays an integrated design and provides the following functional units: A power unit with a circuit arrangement on the upper side of a substrate with power semiconductor components. A cooling unit with a cooling medium flowing through it, which has a heat sink with structured surface formed as an insert section onto which the underside of the substrate is directly fitted. A control unit with semiconductor components arranged on a carrier, which is arranged in parallel to and at a given distance from the substrate of the power unit. Contact pins between the substrate of the power unit and the carrier of the control unit for the connection and contacting of the circuit arrangement of the power unit with the semiconductor components on the control unit. A housing body, which encloses the power unit and the control unit. Two conductor bars which are led parallel to the substrate of the power unit and the carrier of the control unit and out through the housing body for the power supply to the circuit arrangement of the power unit. Connecting bars, which are led out of the housing body and connected to the circuit arrangement of the power unit and/or the semiconductor components of the control unit, for the application of control signals for the control of the power module and/or to tap off output signals from the power module.

U.S. Pat. No. 6,281,649 discloses a dual motor windshield wiper system and windshield washer system integrated together into a single assembly. The system includes two motors (22, 22′), a control circuit (12), a fluid reservoir (120), a pump (112), and at least one mounting member (108, 108′) that supports said motors. The reservoir can be located between the two motors and can be supported in place by the motors. The motors can be thermally coupled to the reservoir so that fluid within the reservoir acts as a heat sink for the motors. The positions of the wipers can be controlled to follow targeted positions that are determined in accordance with acceleration, velocity, and deceleration values that are calculated using a wiper speed setting selected by the vehicle driver.

U.S. Pat. No. 6,710,490 describes a method and apparatus for dissipating heat from electric motors. Small electric motors often operate at undesirably high temperatures and are often mounted to gear cases. To reduce the temperature a thermally conductive gap filling material is compressed between the winding heads of the stator and the mating surface of motor and gear case. The gear case functions as a heat sink for the stator windings. Additional heat sinks may be mounted on the motor housing additional thermally conductive gap filling material compressed between the other winding heads and the cover.

U.S. Pat. No. 6,825,580 explains an apparatus for controlling cooling of a gantry having a linear motor includes: a stator provided with a first temperature sensor, having a heat sink and a cooling fan at predetermined portions of an X-axis and an Y-axis linear motors; a mover provided with a second temperature sensor, having a heat sink installed on the upper surface of an X-axis and a Y-axis linear motors; an encoder for sensing a position and velocity of the mover; an encoder periphery sensor part for measuring surroundings (a temperature, a humidity and a pressure) of the encoder; an A/D converter for receiving a first and a second temperature signals and converting them from an analog signal to a digital signal and outputting the same; a controller for controlling a drive signal outputted from a mover driver unit to control the velocity of the Y-axis linear motor and the X-axis linear motor; a DN converter for converting digital signals, that is, a cooling fan control signal and an air valve control signal to a plurality of drive signals, that is, analog signals; and a mover driver for providing the drive signal to a coil block.

U.S. Pat. No. 6,980,450 discloses a compact high-power pure-sine wave inverter amenable to mass manufacturing techniques. Methods for increasing the power rating, power density and/or power conversion efficiency of a sine wave-modulated pulse-width-modulated (PWM) inverter having a either half-bridge or full-bridge topology, including minimizing uncoupled inductances and loop inductances in the primary winding(s) by employing either ribbon-like conductors having a high crossectional aspect ratio or litz-wire. A compact linear heatsink adapted to cool a row of semiconductor devices (such as inverter switches) mounted on a high-current printed circuit board. Methods for inexpensive manufacture of a fluid-cooled linear heat sink. A transformer including a filter inductor core.

However the purpose and methodology of all the inventions that are part of prior art do not envisage the unique embodiment of the use of a thermally conductive material in a heat sink mechanism in light electric vehicles. The prior art also does not specifically address the concerns of facilitating smooth running of hub motors by withstanding the heat dissipation from inverter switches over long period of time that.

The present invention differs from the existent prior art in that it seeks to extract the heat out of the inverter switches by sandwiching the switches between two thermally conductive rings and also applying pressure on the switches. The pressure increases surface contacts between the inverter switches and the heat sinking metal, thereby, reducing the thermal resistance thereof excellent and stable heat dissipation can be achieved for a long period of time.

It is accordingly an object of the invention to provide an improved heat sink mechanism of the character indicated, inherently avoiding the deficiencies of past systems.

Further it will be apparent to those skilled in the art that the objects of this invention have been achieved by providing a thermally conductive ring encompassed in the heat sink which is unique in nature unlike existing heat sink mechanism in hub motors that are suited only for limited purposes. Various changes may be made in and without departing from the concept of the invention. Further, features of some stages disclosed in this application may be employed with features of other stages. Therefore, the scope of the invention is to be determined by the terminology of the following claims and the legal equivalents thereof.

### SUMMARY OF THE INVENTION

This present invention may be summarized, at least in part, with reference to its objects.

The foremost object of this invention is to provide a heat sink mechanism for internally integrated inverter hub motors with higher heat dissipating capacity as differing from the conventionally low capacity heat sinks.

Another object of the present invention is provide an effective cooling mechanism for the heat generating parts of the hub motors.

Another object of the present invention is to allow for a compactly designed heat sink mechanism by cascading electronic boards one on top of the other with the thermally conductive ring sandwiched in between.

Yet another object of the present invention is to replace the conventional multiple screwing attachment mechanism for attaching the multiple inverter switches to the heat sink.

A further object of the present invention is to provide a thermal conductive ring that doubles as a support to a secondary electronic board in the heat sink mechanism

Additional objects, advantages and novel features of the invention will be set forth in part in the description which follows, and in part will become apparent to those skilled in the art upon examination of the following, or may be learned by practice of the invention.

These and other objects and advantages and features of the present invention will be more readily apparent when considered in reference to the following description and when taken in conjunction with the accompanying drawings listed below.

Image 1 is an exploded view of the parts in a conventional heat sink mechanism.

Image 2 is a perspective view of the conventional heat sink mechanism.

Image 3 is an exploded view of the parts in the present heat sink mechanism.

Image 4 is a perspective view of the present heat sink mechanism.

### DETAILED DESCRIPTION OF THE INVENTION

The following description is presented to enable any person skilled in the art to make and use the invention, and is provided in the context of particular applications of the invention and their requirements. The present invention can be configured as follows:

Hub motors are the propulsion units for light electric vehicles. In some hub motors the DC to AC inverters are integrated within the motor itself. Heat is generated by the inverter placed inside the motor and hence an effective cooling mechanism has to be devised for the proper functioning of the motors.

The present invention envisages an effective and improved heat dissipation mechanism for a heat sink assembly of an internally integrated inverter hub motor by sandwiching a thermally conducive ring with the conventional heat sink and the electronic board consisting of the multiple inverter switches. This invention extracts the heat out of the inverter switches by sandwiching the switches between two thermally conductive rings and also applying pressure on the switches. The pressure increases surface contacts between the inverter switches and the heat sinking metal, thereby, reducing the thermal resistance.

The present invention is designed for use in any hub motor of an output power of 500 Watts or more, air cooled or liquid cooled, and used for light electric vehicles or electric cars. Light electric vehicle includes any vehicle 1-wheel or 2-wheel or 3-wheel or 4-wheel which is powered by an electric motor with an output power of less than 15 kW.

The present invention consists of a heat sink assembly comprising of a thermally conducive ring, the electronic board consisting of multiple inverter switches, a potential secondary electronic board and a heat sink base. The thermally conducive ring is made up of a metal having a coefficient of thermal conductivity higher than that of aluminum because it requires high thermal diffusivity and improved cooling for the heat generating parts of the hub motors. The heat sink is made up of metal like aluminum or aluminum alloy and is designed to look like a circular metallic base bent inwardly to form a container like structure. The conventional heat sink has low heat dissipating capacity.

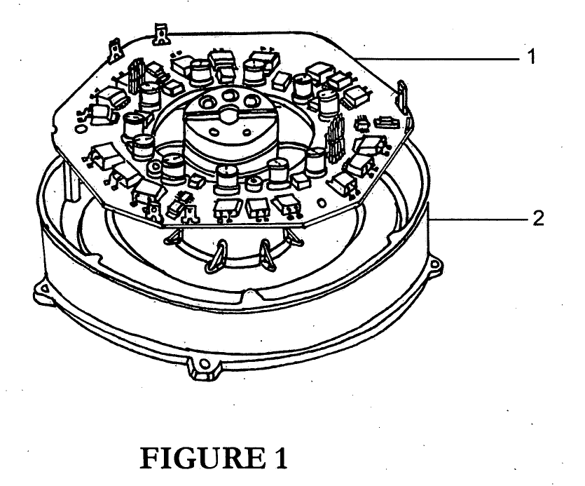

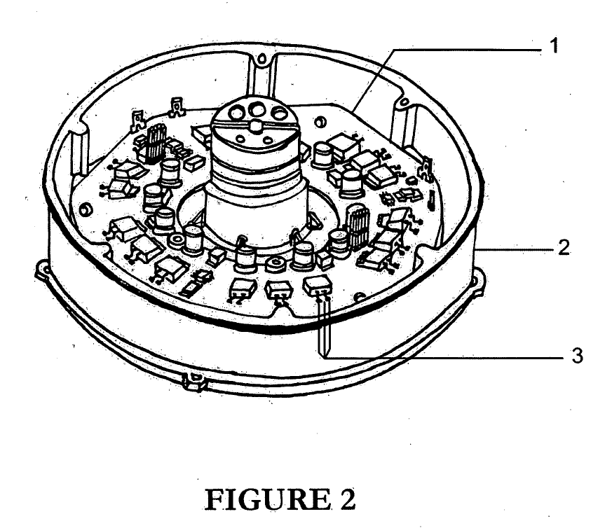

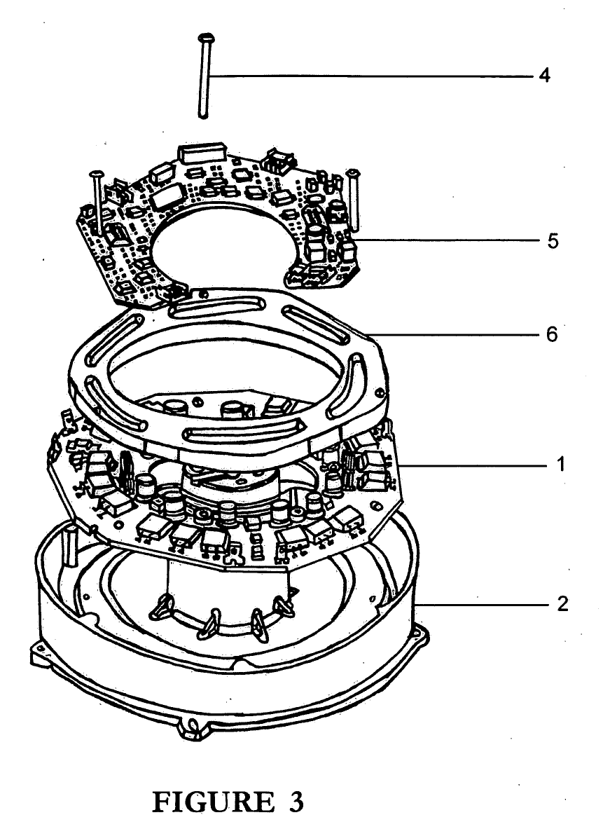

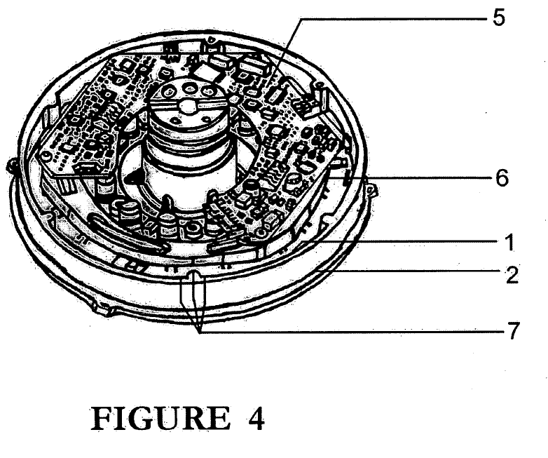

FIGS. 1 and 2 details the parts of a conventional heat sink mechanism wherein an electronic board with 12 switches is positioned on a heat sink and the switches are fixed separately on the heat sink. FIGS. 3 and 4 illustrates the parts of the present invention, comprising of a thermally conductive ring sandwiching switches with the conventional heat sink, said ring also acting as a support to a secondary electronic board.

In the conventional system of heat sink assembly the inverter switch is screwed to the sides of the heat sink metallic base plate. Thus the usual way to dissipate heat from an inverter switch is to screw the switch to a one sided heat sink, as depicted in FIGS. 1 and 2. FIGS. 1 and 2 shows unidirectional way of heat dissipation (3) from the main electronic board (1) to the hub/heat sink (2). For a multi-switch inverter multiple screws or attachment mechanism is required to attach the switches to the heat sink. Here in the present invention the heat sink assembly works by pressing the thermally conductive one piece ring against the electronic board containing multiple inverter switches which is just placed on the conventional heat sink base. This arrangement sandwiches the inverter switches in between the thermally conductive one ring and the conventional heat sink and allows heat dissipation through the conventional heat sink and also through the thermally conductive one piece ring, and thereby maintains stable temperature of the inverter switches. FIGS. 2 and 3 shows how the thermally conductive ring (6) is screwed (4) into the existing system and sandwiches the main electronic board (1) between the hub/heat sink (2) and the ring (6), thereby, creating a bidirectional heat dissipation (7) from the main electronic board. Also the pressure generated by the ring on the main electronic board improves the heat dissipation (7). Further the present invention consists of a heat sink comprising a base, which is composed of a thermally conductive ring having a coefficient of thermal conductivity higher than that of aluminum.

Furthermore, an added advantage of the present invention is that the thermally conductive ring can support a secondary electronic board on top of it. The secondary electronic board can be placed on the top of the thermally conductive ring which serves as a support for the electronic board and provides a compact design for internally integrated inverter hub motors used in light electric vehicles. FIGS. 3 and 4 of the present invention clearly illustrates the complete heat sink assembly with the thermally conductive ring supporting a secondary electronic board.

The present invention thus envisages a mechanism for heat dissipation by pressing down a thermally conductive one piece ring on the inverter switches to affix the switches to the hub of the motor. In this way the switches are sandwiched between the heat conductive hub and the pressure ring as depicted in FIGS. 3 and 4. This mechanism increases heat dissipation through the hub and the pressure ring and also allows uniform temperature among the inverter switches. An added advantage of this mechanism is, electronic boards can be cascaded one on top other with the thermally conductive ring sandwiched in between. This allows a compact design which is necessary for an internally integrated inverter hub motors designed for light electric vehicle.

While there has been shown and described what is considered to be preferred embodiments of the invention, it will, of course, be understood that various modifications and changes in form or detail could readily be made without departing from the spirit of the invention. It is therefore intended that the invention be not limited to the exact forms described and illustrated, but should be constructed to cover all modifications that may fall within the scope of the appended claims.

It will be apparent to those skilled in the art that the objects of this invention have been achieved by providing the above invention. However various changes may be made in the structure of the invention without departing from the concept of the invention. Therefore, the scope of the invention is to be determined by the terminology of the following claims and the legal equivalents thereof.

What is claimed is:

1. A heat sink mechanism for internally integrated inverter hub (I³H) motor with an output power equal to or more than 500 watts for light electric vehicles comprised of a thermally conductive ring, an electronic board, and a heat sink base characterized in that said electronic board consists of multiple inverter switches.

2. A heat sink mechanism as claimed in claim 1 wherein said electronic board containing multiple inverter switches is placed on top of said heat sink base.

3. A heat sink mechanism as claimed in claim 1 wherein said thermally conductive one piece ring is placed on top of said electronic board.

4. A heat sink mechanism as claimed in claim 1 wherein a secondary electronic board may be placed on the top of said thermally conductive ring.

5. A heat sink mechanism as claimed in claim 1 wherein said thermally conductive ring is made up of metals like copper, gold or their alloys or any metal having thermal conductivity higher than the coefficient of thermal conductivity of aluminum alloy.

6. A heat sink mechanism as claimed in claim 1 wherein said conventional heat sink is a circular metallic base bent inwardly to form a container like structure and made up of metal like aluminum or aluminum alloy.

7. A heat sink mechanism as claimed in claim 1 wherein said hub motor may be air cooled or liquid cooled.

8. A heat sink mechanism as claimed in claim 1 wherein said light electric vehicle is a vehicle 1-wheel or 2-wheel or 3-wheel or 4-wheel and powered by an electric motor with an output power of less than 20 kW.
